(19) United States
(12) Patent Application Publication
(10) Pub. No.: US 2024/0213374 A1
(43) Pub. Date: Jun. 27, 2024

(54) PANEL STRUCTURE AND PREPARING METHOD THEREOF

(71) Applicant: Guangzhou China Star Optoelectronics Semiconductor Display Technology Co., LTD., Guangzhou (CN)

(72) Inventor: Cheng GONG, Guangzhou (CN)

(73) Assignee: Guangzhou China Star Optoelectronics Semiconductor Display Technology Co., LTD., Guangzhou (CN)

(21) Appl. No.: 18/522,302

(22) Filed: Nov. 29, 2023

(30) Foreign Application Priority Data
Dec. 21, 2022 (CN) 202211649875.5

(51) Int. Cl. H01L 29/786; H01L 29/66

(52) U.S. Cl. CPC H01L 29/7869; H01L 29/66742

(57) ABSTRACT

Provided are a panel structure and a preparing method thereof. The panel structure comprises a glass substrate, a first insulating layer, a semiconductor device layer, and a second insulating layer. The second insulating layer coincides with the first device part in a direction perpendicular to a thickness of the glass substrate, and an energy band gap of a second material of the second insulating layer is less than an energy band gap of a first material of the semiconductor device layer.

### CROSS-REFERENCE TO RELATED APPLICATION

This application claims the benefit of priority to Chinese Patent Application No. 202211649875.5, filed on Dec. 21, 2022, the contents of which are all incorporated by reference as if fully set forth herein in their entirety.

### FIELD

The present disclosure relates to liquid crystal display technologies, and in particular, to a panel structure and a preparing method thereof.

### BACKGROUND

There are mainly two types of thin film transistors (TFTs) in a TFT device layer of a liquid crystal panel, one type is a TFT constituting a display area (AA), and another type is a TFT which is outside the AA and constitutes a peripheral driving circuit area (GOA).

In a working process, the GOA needs to work under a high positive bias voltage for a long time. Thus, serious heat generation is caused, and corresponding positive bias stability will deteriorate.

An existing solution is to keep a relative high carrier concentration in the GOA by increasing illumination received by a device layer, so as to improve the stability of the GOA.

However, at present, a problem of such a solution is that: since the AA is affected by illumination for a long time, photogenerated electrons increase, and Vth of a TFT device tends to move negatively, thereby leading to the decline of the stability of the AA.

### SUMMARY

A panel structure according the present disclosure includes: a glass substrate having a first surface; a first insulating layer on the first surface; a semiconductor device layer on the first insulating layer, the semiconductor device layer comprising a first device part and a second device part, a region occupied by the first device part corresponding to a display area of the panel structure, and a region occupied by the second device part corresponding to a peripheral driving circuit area of the panel structure; and a second insulating layer between the first device part and the first insulating layer, the second insulating layer coinciding with the first device part in a direction perpendicular to a thickness of the glass substrate; the semiconductor device layer being made of a first material, the second insulating layer being made of a second material; an energy band gap of the second material being less than an energy band gap of the first material.

In one or more embodiments of the present disclosure, the first material is indium gallium zinc oxide; and the first insulating layer is made of silicon oxide.

In one or more embodiments of the present disclosure, the second material is any one of titanium dioxide, zinc oxide, indium trioxide, cadmium sulfide, or cadmium selenide.

In one or more embodiments of the present disclosure, the energy band gap of the second material is less than 3.2 eV.

In one or more embodiments of the present disclosure, the panel structure further includes a first metal layer, the first metal layer is disposed on the first surface and covers part of the first surface; the first insulating layer covers the first metal layer and part of the first surface not covered by the first metal layer; and the semiconductor device layer is disposed in a region of the first insulating layer corresponding to the first metal layer.

In one or more embodiments of the present disclosure, the panel disclosure further includes a third insulating layer, and the third insulating layer covers the second metal layer and a region of the first insulating layer not covered by the second metal layer.

In one or more embodiments of the present disclosure, a through hole is defined in a region of the third insulating layer corresponding to the second metal layer, part of the second metal layer is exposed from the through hole; the panel structure further includes a conductive layer, the conductive layer is disposed on the third insulating layer, and part of the conductive layer is filled in the through hole and is connected to the second metal layer.

A preparing method of a panel structure according to one or more embodiments of the present disclosure includes: providing a glass substrate, the glass substrate having a first surface; depositing a first original metal layer on the first substrate, and patterning the first original metal layer to form a first metal layer, the first metal layer including a first circuit structure corresponding to a display area and a second circuit structure corresponding to a peripheral driving circuit area; forming a first insulating layer on the first metal layer and part of the first surface not covered by the first metal layer; forming a second insulating layer in a region of the first insulating layer corresponding to the first circuit structure; and forming a semiconductor device layer on the first insulating layer and the second insulating layer; the semiconductor device layer being made of a first material, the second insulating layer being made of a second material; and an energy band gap of the second material being less than an energy band gap of the first material.

In one or more embodiments of the present disclosure, the forming of the second insulating layer in a region of the first insulating layer corresponding to the first circuit structure includes: depositing the second insulating layer on the first insulating layer to cover the first insulating layer; coating photoresist in a region of the second insulating layer corresponding to the first circuit structure to form a photoresist layer; removing part of the second insulating layer not coated with the photoresist, remaining part of the second insulating layer coated with the photoresist, the second insulating layer coinciding with a region of the first insulating layer corresponding to the first circuit structure; and removing the photoresist layer on the second insulating layer.

In one or more embodiments of the present disclosure, the preparing method of the panel structure further includes: depositing a second original metal layer on the semiconductor device layer, patterning the second original metal layer to form a second metal layer; depositing a third insulating layer on the second metal layer and a region of the first insulating layer not covered by the second metal layer; forming a through hole on the third insulating layer to expose part of the second metal layer from the through hole; and depositing a conductive layer on the third insulating layer, part of the conductive layer being filled in the through hole and being connected to the second metal layer.

### BRIEF DESCRIPTION OF THE DRAWINGS

In order to explain technical solutions in one or more embodiments of the present disclosure or the related art more clearly, accompanying drawings needed to be used in the description of one or more embodiments or the related art will be briefly introduced hereinafter. Apparently, the accompanying drawings in the following description are merely one or more embodiments of the present disclosure, and other drawings may also be obtained according to the structures shown in these accompanying drawings without creative work for the skilled in the art.

FIG. 1 illustrates a schematic diagram of preparing a first metal layer in a preparing method of a panel structure according to one or more embodiments of the present disclosure.

FIG. 2 illustrates a schematic diagram of preparing a first insulating layer in the

preparing method of a panel structure according to one or more embodiments of the present disclosure.

FIG. 3 illustrates a schematic diagram of depositing a second insulating layer in a preparing method of a panel structure according to one or more embodiments of the present disclosure.

FIG. 4 illustrates a schematic diagram of coating photoresist in a preparing method of a panel structure according to one or more embodiments of the present disclosure.

FIG. 5 illustrates a schematic diagram of forming a second insulating layer covering only a display area in a preparing method of a panel structure according to one or more embodiments of the present disclosure.

FIG. 6 illustrates a schematic diagram of preparing a semiconductor device layer in a preparing method of a panel structure according to one or more embodiments of the present disclosure.

FIG. 7 illustrates is a schematic diagram of preparing a second metal layer in a

preparing method of a panel structure according to one or more embodiments of the present disclosure.

FIG. 8 illustrates is a schematic diagram of preparing a third insulating layer in the preparing method of a panel structure according to one or more embodiments of the present disclosure.

FIG. 9 illustrates is a schematic diagram of preparing a conductive layer in a preparing method of a panel structure according to one or more embodiments of the present disclosure.

### DETAILED DESCRIPTION

The technical solutions in one or more embodiments of the present disclosure will be clearly and completely described with reference to the accompanying drawings. Apparently, the described embodiments are only part but not all of the embodiments of the present disclosure. Based on one or more embodiments in the present disclosure, all other embodiments obtained by those skilled in the art without creative work fall within the scope of the present disclosure.

In addition, if there are descriptions related to “first” and “second” in one or more embodiments of the present disclosure, the descriptions of “first” and “second” are merely used for descriptive purposes, and cannot be understood as indicating or implying their relative importance or implicitly indicating the number of indicated technical features. Therefore, the features defined by “first” and “second” may explicitly or implicitly include at least such feature. In addition, the meaning of “and/or” appearing in the present disclosure includes three parallel solutions. Taking “A and/or B” as an example, “A and/or B” includes a solution A, a solution B, or a solution in which A and B are included. In addition, the technical solutions of different embodiments may be combined with each other, but the combination must be based on that those skilled in the art can implement. When the combination of technical solutions is contradictory or impossible, it should be considered that the combination of technical solutions does not exist and is not within the scope of the present disclosure.

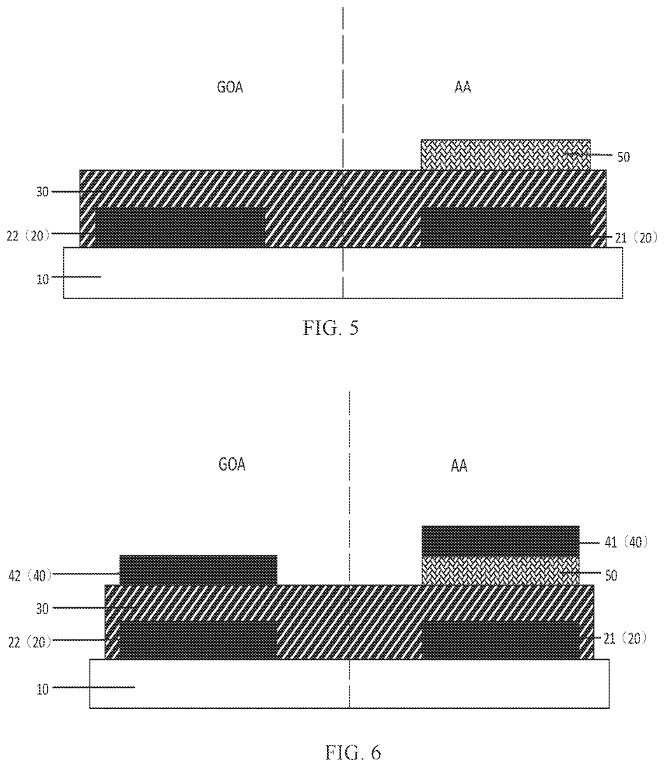

As shown in FIG. 6, a panel structure according to the present disclosure includes a glass substrate 10, a first metal layer 20, a first insulating layer 30, a semiconductor device layer 40, and a second insulating layer 50.

The glass substrate 10 has a first surface. The first surface is used as a load bearing layer of a panel structure and a protective layer of the panel structure, and is disposed between other layers and a backlight source.

The first metal layer 20 is disposed on the first surface of the glass substrate 10 and covers the first surface. Actually, there are multiple first metal layers 20 on the glass substrate, that is, each first metal layer 20 covers only part of the first surface.

The first insulating layer 30 covers the first metal layer 20 and part of the first surface not covered by the first metal layer 20.

The semiconductor device layer 40 is disposed on the first insulating layer 30 and disposed in a region of the first insulating layer 30 corresponding to the first metal layer 20. The semiconductor device layer 40 includes a first device part 41 and a second device part 42. A region occupied by the first device part 41 corresponds to a display area of the panel structure, and a region occupied by the second device part 42 corresponds to a peripheral driving circuit area of the panel structure.

The second insulating layer 50 is disposed between the first device part 41 and the first insulating layer 30. The second insulating layer 50 completely coincides with the first device part 41 in a direction perpendicular to a thickness of the glass substrate 10.

The semiconductor device layer 40 is made of a first material, and the second insulating layer 50 is made of a second material.

An energy band gap of the second material is less than that of the first material.

It should be noted that the semiconductor device layer 40, that is, a layer structure including TFTs, has a first device part 41 including TFTs disposed in the display area, and a second device part 42 including TFTs disposed in the peripheral driving circuit area.

In one or more embodiments, other functional layers may be arranged between the first insulating layer 30 and the first surface of the glass substrate 10.

It can be understood that since the TFTs included in the peripheral driving circuit

area are configured for turning on a whole row of gates, large driving current and correspondingly increased TFT size are required. Thus, the TFTs need to work at a high positive bias voltage, thereby causing serious heat generation. Therefore, the corresponding positive bias stability will deteriorate.

In order to eliminate such influence, the TFT may be kept at a relative high carrier

concentration, so as to improve positive bias stability of the peripheral driving circuit area.

It should be understood that, the mechanism of Positive Bias Temperature Stress (PBTS) is that electrons are constantly trapped under Gate positive stress, thus a turn- on voltage is increased and the PBTS deteriorates. Photogenerated electrons is generated under illumination, and carrier concentration in an active layer increases. The increase of electrons in a bulk can balance and offset the electron trap caused by the PBTS, and the PBTS is improved.

However, since a general semiconductor device layer 40 is made of indium gallium zinc oxide (IGZO), under illumination, high-energy ultraviolet will excite the IGZO and a large number of photogenerated electrons are generated, causing deterioration of Negative Bias Temperature Instability stress (illumination stability, NBTIS) and decrease of the stability of the first device part 41 in the display area.

Therefore, it is necessary to ensure the stability of both the TFTs in the peripheral driving circuit area and the TFTs in the display area in the panel structure under the action under illumination. One feasible way is to filter out the high-energy ultraviolet in the illumination before illumination reaches the display area.

Therefore, in a panel structure according to the present disclosure, a second insulating layer 50 is arranged between the semiconductor device layer 40 and the first insulating layer 30, the second insulating layer 50 covers only part of the semiconductor device layer 40 corresponding to the display area, and an energy band gap of a second material of the second insulating layer 50 is less than an energy band gap of a first material of the semiconductor device layer 40. It can be understood in response to determining that the energy band gap of the second material is less than the energy band gap of the first material, most of the ultraviolet can be absorbed, and remaining ultraviolet is not enough to excite the semiconductor device layer 40 to generate photogenerated electrons, so that the illumination stability of the semiconductor device layer 40 in the display area can be effectively improved. In addition, illumination can keep the semiconductor device layer 40 in the peripheral driving circuit area at a relative high carrier concentration, therefore, the positive bias stability of the peripheral driving circuit can be improved. That is to say, through the above arrangement, the panel structures according to the present disclosure can keep both the stability of the peripheral drive circuit area and the stability of the display area under long-time illumination.

In one or more embodiments, the first metal layer 20 is generally used as a gate metal layer, and the first metal layer 20 is generally made of titanium(Ti)/aluminum(Al)/Ti or molybdenum (Mo)/Al/Mo.

In one or more embodiments, there are generally multiple first metal layers 20, which are spaced on the glass substrate 10.

In one or more embodiments, the second insulating layer 50 is arranged in a two- layer or multiple-layer structure. Part of the second insulating layer 50 is disposed between the first insulating layer 30 and the first metal layer 20, and another part of the second insulating layer 50 is disposed between the first insulating layer 30 and the semiconductor device layer 40. That is to say, by dividing the second insulating layer 50 into two parts, the ultraviolet in illumination can be absorbed twice, thereby improving an ultraviolet absorption rate of the second insulating layer 50.

In one or more embodiments, the first material is IGZO, that is, indium gallium zinc oxide. The first insulating layer 30 is made of silicon oxide (SiOx).

It should be noted that, according to the specification of the prepared semiconductor device layer 40, the energy band gap of the IGZO is in a range from 3.2 eV to 3.7 eV.

Therefore, in order to make the second insulating layer 50 effectively filter out the ultraviolet from the backlight, it is required that the energy band gap of the second material of the second insulating layer 50 is less than 3.2 eV.

Based on the above solutions, those skilled in the art may select any one of titanium dioxide, zinc oxide, indium trioxide, cadmium sulfide, or cadmium selenide as the second material, and an energy band gap of each of the above materials is less than 3.2 eV. Therefore, ultraviolet with a wavelength λ<387 nanometers (nm) can be filtered out, and without filtered light with λ<387 nm, the remaining visible light is not enough to excite the IGZO to generate photogenerated electrons, so that the illumination stability of the IGZO can be effectively improved.

Therefore, since the second insulating layer 50 made of the above material is disposed below the semiconductor device layer 40 made of IGZO, ultraviolet from the backlight can be effectively filtered out, so that an IGZO semiconductor of the TFT is prevented from being illuminated by the ultraviolet to generate the photogenerated electrons, thereby effectively improving the stability of the IGZO TFT.

It can be understood that in a case that the semiconductor device layer 40 is made of other materials, the second insulating layer 50 may be made of other materials with an energy band gap less than the energy band gap of the semiconductor device layer 40, which will not be described herein.

It should be noted that the energy band gap, also known as energy gap or band gap, generally refers to an energy gap between a top of valence band and a bottom of conduction band of a semiconductor or an insulator in solid state physics.

As shown in FIG. 7, in one or more embodiments, the panel structure further includes a second metal layer 60, and the second metal layer 60 is disposed on the semiconductor device layer 40 and covers only a region corresponding to the first metal layer 20.

It should be noted that, in one or more embodiments, the second metal layer 60 is generally made of materials of Ti/Al/Ti or Mo/Al/Mo materials, and is used as source drain layer of the panel structure.

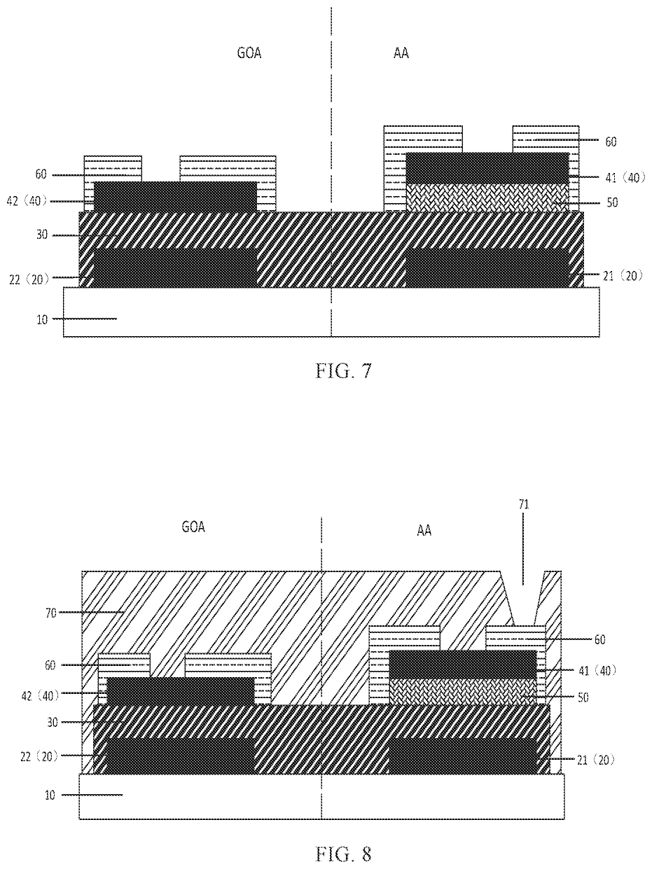

As shown in FIG. 8, in one or more embodiments, the panel structure further includes a third insulating layer 70, and the third insulating layer 70 covers the second metal layer 60 and a region of the first insulating layer 30 not covered by the second metal layer 60.

It should be noted that, in one or more embodiments, the third insulating layer 70 is made of SiOx and SiNx, and is used as an insulating shielding layer.

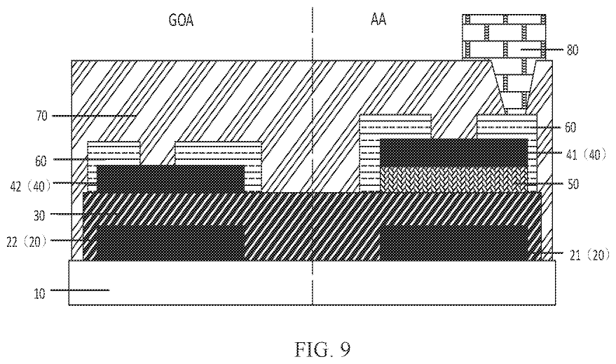

As shown in FIG. 9, further, in one or more embodiments, a through hole 71 is defined in a region of the third insulating layer 70 corresponding to the second metal layer 60, and part of the second metal layer 60 is exposed from the through hole 71. The panel structure also includes a conductive layer 80, and the conductive layer 80 is disposed on the third insulating layer 70. Part of the conductive layer 80 is filled in the through hole 71 and is connected to the second metal layer 60.

It should be noted that, the conductive layer 80 may be made of indium tin oxide (ITO).

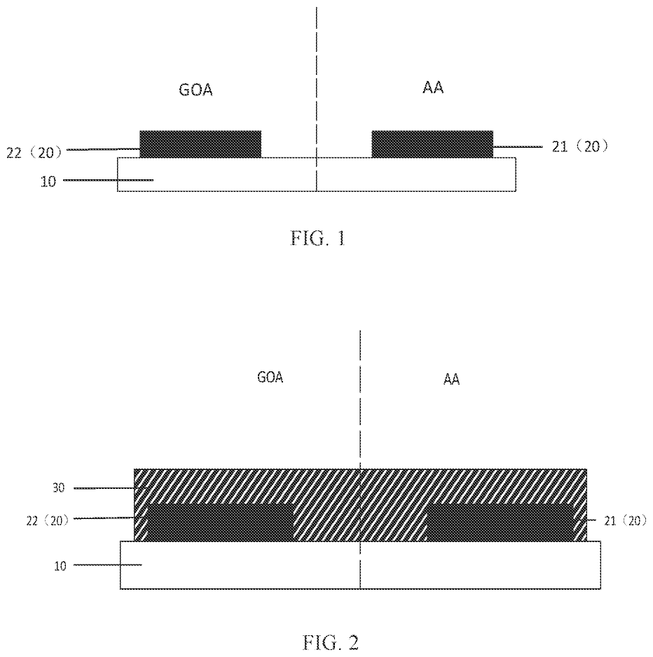

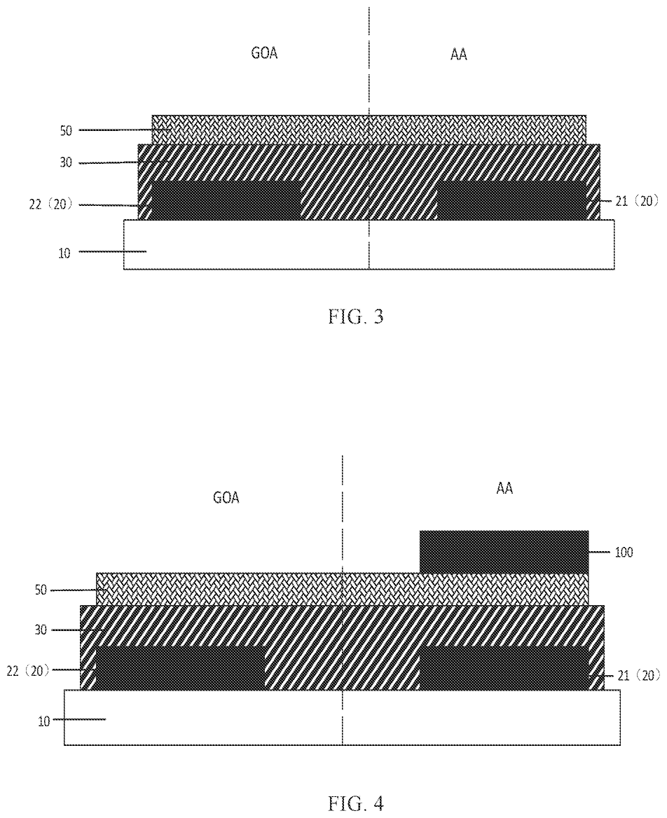

As shown in FIGS. 1 to 6, a preparing method for preparing the above panel structure according to one or more embodiments of the present disclosure includes steps S010 to S400.

In S010, a glass substrate 10 is provided, the glass substrate 10 is used as a load bearing layer, and the glass substrate 10 has a first surface.

In S100, a metal layer M1 deposited on the first surface, and the metal layer M1 is patterned to form multiple first metal layers 20 spaced on the first surface. At least one of the first metal layers 20 includes a first circuit structure 21 corresponding to a display area and a second circuit structure 22 corresponding to a peripheral driving circuit area.

It should be noted that the first circuit structure 21 refers to part of the first metal layer 20 disposed in the display area of the panel structure, and the second circuit structure 22 refers to part of the first metal layer 20 disposed in the peripheral driving circuit area of the panel structure.

In S200, a first insulating layer 30 is formed on the first metal layer 20 and part of the first surface not covered by the first metal layer 20.

In S300, a second insulating layer 50 is formed in a region of the first insulating layer 30 corresponding to the first circuit structure 21.

It should be noted that the second insulating layer 50 formed in S300 coincides with only a region of the first insulating layer 30 corresponding to the first circuit structure 21.

In S400, a semiconductor device layer 40 is formed on the first insulating layer 30 and the second insulating layer 50.

The semiconductor device layer 40 is made of a first material, and the second insulating layer 50 is made of a second material. An energy band gap of the second material is less than an energy band gap of the first material.

It should be noted that in S300, the second insulating layer 50 is made of titanium dioxide.

The titanium dioxide in S300 may also be replaced by any one of zinc oxide, indium trioxide, cadmium sulfide, or cadmium selenide.

On the other hand, in S200, the first insulating layer 30 is formed on the glass substrate 10 by chemical vapor deposition under the following deposition conditions: Electromagnetic pulse (Emp): 340-380; Power: 1000 W-140 0W; Pressure: 500 metric tons (mt)-800 mt; Spacing: 400 mil (one thousandth of an inch)-600 mil; Silicon tetrahydride: 0-400 standard-state cubic centimeters per minute (sscm); and Nitrogen dioxide: 24000 sscm.

Further, In S300, the forming of the second insulating layer 50 in the region of the first insulating layer 30 corresponding to the first circuit structure 21 includes steps S301-S304.

In S301, the second insulating layer 50 is deposited on the first insulating layer 30 to completely cover the first insulating layer 30.

In S302, photoresist 100 is coated in a region of the second insulating layer 50 corresponding to the display area to form a photoresist layer 100.

In S303, part of the second insulating layer 50 not coated with the photoresist 100 is removed, and part of the second insulating layer 50 coated with the photoresist 100 is remained, so that the second insulating layer 50 completely coincides with a region of the first insulating layer 30 corresponding to the display area.

In S304, the photoresist layer 100 on the second insulating layer 50 is removed.

Further, In Step S301, the second insulating layer 50 completely covering the first insulating layer 30 is deposited on the first insulating layer 30 by physical vapor deposition under the following deposition conditions: Power: 9 kilowatts (kw); Ar: 100 sccm; Oxygen: 43 sccm; and Pressure: 0.6 pascals (Pa).

It should be explained that in S303, the photoresist 100 is generally removed by etching.

As shown in FIGS. 7 to 9, further, in one or more embodiments, the preparing method of the panel structure further includes steps S500 to S800.

In S500, a metal layer M2 is deposited on the semiconductor device layer 40,

and the metal layer M1 is patterned to form a second metal layer 60.

In S600, a third insulating layer 70 is deposited on the second metal layer 60 and a region of the first insulating layer 30 not covered by the second metal layer 60.

In S700, a through hole 71 is defined in a region of the third insulating layer 70 corresponding to the second metal layer 60. Part of the second metal layer 60 is exposed from the through hole 71.

In S800, a conductive layer 80 is deposited on the third insulating layer 70. Part of the conductive layer 80 is filled in the through hole 71 and is connected to the second metal layer 60.

The above is merely optional embodiments of the present disclosure, which does not limit the scope of the present disclosure. All equivalent structural transformations made by using the contents of the specification and drawings of the present disclosure or direct/indirect application in other related technical fields are included in the scope of protection of the present disclosure.

What is claimed is:

1. A panel structure, comprising:
a glass substrate having a first surface;
a first insulating layer on the first surface;
a semiconductor device layer on the first insulating layer, wherein the semiconductor device layer comprises a first device part and a second device part, a region occupied by the first device part corresponds to a display area of the panel structure, and a region occupied by the second device part corresponds to a peripheral driving circuit area of the panel structure; and
a second insulating layer between the first device part and the first insulating layer, wherein the second insulating layer coincides with the first device part in a direction perpendicular to a thickness of the glass substrate;
wherein the semiconductor device layer is made of a first material, and the second insulating layer is made of a second material; and
wherein an energy band gap of the second material is less than an energy band gap of the first material.

2. The panel structure according to claim 1, wherein the first material is indium gallium zinc oxide; and
the first insulating layer is made of silicon oxide.

3. The panel structure according to claim 2, wherein the second material is any one of titanium dioxide, zinc oxide, indium trioxide, cadmium sulfide, or cadmium selenide.

4. The panel structure according to claim 1, wherein the panel structure further comprises a first metal layer, and the first metal layer is disposed on the first surface and covers part of the first surface; the first insulating layer covers the first metal layer and part of the first surface not covered by the first metal layer; and the semiconductor device layer is disposed in a region of the first insulating layer corresponding to the first metal layer.

5. The panel structure according to claim 4, further comprising a second metal layer, wherein the second metal layer covers a region of the semiconductor device layer corresponding to the first metal layer.

6. The panel structure according to claim 5, further comprising a third insulating layer, wherein the third insulating layer covers the second metal layer and a region of the first insulating layer not covered by the second metal layer.

7. The panel structure according to claim 6, wherein a through hole is defined in a region of the third insulating layer corresponding to the second metal layer, part of the second metal layer is exposed from the through hole; and
the panel structure further comprises a conductive layer, the conductive layer is disposed on the third insulating layer, and part of the conductive layer is filled in the through hole and is connected to the second metal layer.

8. A preparing method of a panel structure, comprising:
providing a glass substrate, wherein the glass substrate has a first surface;
depositing a first original metal layer on the first substrate, and patterning the first original metal layer to form a first metal layer, wherein the first metal layer comprises a first circuit structure corresponding to a display area and a second circuit structure corresponding to a peripheral driving circuit area;
forming a first insulating layer on the first metal layer and part of the first surface not covered by the first metal layer;
forming a second insulating layer in a region of the first insulating layer corresponding to the first circuit structure; and
forming a semiconductor device layer on the first insulating layer and the second insulating layer;
wherein the semiconductor device layer is made of a first material, and the second insulating layer is made of a second material; and
wherein an energy band gap of the second material is less than an energy band gap of the first material.

9. The preparing method of the panel structure according to claim 8, wherein the forming of the second insulating layer in a region of the first insulating layer corresponding to the first circuit structure comprises:
depositing the second insulating layer on the first insulating layer to cover the first insulating layer;
coating photoresist in a region of the second insulating layer corresponding to the first circuit structure to form a photoresist layer;
removing part of the second insulating layer not coated with the photoresist, and remaining part of the second insulating layer coated with the photoresist, so that the second insulating layer coincide with a region of the first insulating layer corresponding to the first circuit structure; and
removing the photoresist layer on the second insulating layer.

10. The preparing method of the panel structure according to claim 8, further comprising:
depositing a second original metal layer on the semiconductor device layer, and patterning the second original metal layer to form a second metal layer;
depositing a third insulating layer on the second metal layer and a region of the first insulating layer not covered by the second metal layer;
forming a through hole on the third insulating layer to expose part of the second metal layer from the through hole; and
depositing a conductive layer on the third insulating layer, wherein part of the conductive layer is filled in the through hole and is connected to the second metal layer.
